(19) United States
(12) Patent Application Publication
(10) Pub. No.: US 2006/0255336 A1
(43) Pub. Date: Nov. 16, 2006

(54) Thin film transistor and method of manufacturing the same

(76) Inventor: Sung-Jin Kim, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/430,365

(22) Filed: May 8, 2006

(30) Foreign Application Priority Data
May 10, 2005 (KR) 10-2005-0038978

(51) Int. Cl. H01L 51/00; H01L 51/56

(52) U.S. Cl. 257/40; 438/466

(57) ABSTRACT

A thin film transistor (TFT), a method of manufacturing the same, and a flat panel display including the TFT are disclosed. The TFT includes: a gate electrode; source and drain electrodes insulated from the gate; a polymer organic semiconductor layer. The organic semiconductor layer is insulated from the gate electrode, and is electrically connected to the source and drain electrodes. The organic semiconductor layer includes a channel region that is molecularly ordered by applying a voltage to the gate electrode. The TFT also includes a gate insulating layer that insulates the gate electrode from the source and drain electrodes. In the TFT, the active channel region of the polymer organic semiconductor layer has a charge transport medium having an increased packing density so that more current can flow between the source electrode and the drain electrode and the on/off ratio can be increased. The TFT is suitable for a large, reliable organic light emitting display or a large flexible display driving device.

### CROSS-REFERENCE TO RELATED APPLICATIONS

This application claims the benefit of Korean Patent Application No. 10-2005-0038978, filed on May 10, 2005, in the Korean Intellectual Property Office, the disclosure of which is incorporated herein in its entirety by reference.

### BACKGROUND OF THE INVENTION

1. Field of the Invention

The present invention relates to a thin film transistor and a method of manufacturing the same, and more particularly, to a thin film transistor including an organic semiconductor layer and a method of manufacturing the same.

2. Description of the Related Technology

In flat panel displays, such as a liquid crystal display, an organic light emitting display, or an inorganic light emitting display, thin film transistors (TFTs) are used to serve, for example, as switching devices that control the operation of respective pixels and as driving devices that drive the pixels.

A TFT typically includes a semiconductor layer, a gate electrode, and an insulating layer interposed between the semiconductor layer and the gate electrode. The semiconductor layer has source and drain regions and a channel region interposed between the source and drain regions. The gate electrode overlaps with the channel region and is insulated from the semiconductor layer. Source and drain electrodes are configured to contact the source and drain regions, respectively.

In general, the source and drain electrodes are formed of a low work function metal so that charges can flow smoothly. However, a region where such a metal contacts the semiconductor layer has a high contact resistance. As a result, such a TFT may lack desired characteristics, and have a high power consumption.

Organic TFTs include organic semiconductor layers as a channel. Such organic semiconductor layers can be produced by a low temperature process, and thus, a variety of substrates, including plastic substrates, can be used in organic TFTs.

In conventional organic TFTs, organic semiconductor layers are formed of low molecular weight organic semiconductors. It has been found that alignment or ordering of molecules of such organic semiconductors leads to an increase in charge mobility within the organic semiconductor layers. In order to align molecules of a low molecular weight organic semiconductor compound, the compound is vacuum-deposited and then a rubbing treatment or photo-alignment is performed. See Swiggers et al, ORIENTATION OF PENTACENE FILMS USING SURFACE ALIGNMENT LAYERS AND ITS INFLUENCE ON THIN-FILM TRANSISTOR CHARACTERISTICS, Applied Physics Letters, Vol. 79, No. 9, pp 1300-1302 (2001).

However, forming a low molecular organic semiconductor layer that is molecularly ordered as described above requires a deposition apparatus, and such a layer is not suitable for a large screen organic light emitting display. Due to these problems, polymeric organic semiconductor compounds have been studied to replace the low molecular weight organic semiconductor compounds with larger organic semiconductor materials.

### SUMMARY OF CERTAIN INVENTIVE ASPECTS

One aspect of the invention provides a thin film transistor (TFT) including a polymer organic semiconductor layer that is efficiently molecularly ordered, a method of manufacturing the same, and a reliable flat panel display including the TFT.

Another aspect of the invention provides a method of making an electronic device comprising an organic semiconductor layer. The method comprises forming an organic semiconductor layer on a surface with an organic material; and applying an electric field over the surface so as to align at least part of the organic material.

In the method, the electric field may be applied while depositing the organic material. The method may further comprise: providing an electrode; and providing an insulating layer over the electrode. The insulating layer may provide the surface, on which the organic semiconductor layer is formed; and applying the electric field may comprise applying a voltage to the electrode.

The organic material may comprise a p-type organic compound, and the voltage may be negative. The voltage may range from about −100V to about −50V. The organic material may comprise an n-type organic compound, and the voltage may be positive. The voltage may range from about 50V to about 100V.

The insulating layer may comprise a material having a dielectric constant between about 3.9 and about 10. The electronic device may comprise a thin film transistor, and the thin film transistor may comprise a channel, a gate electrode, an insulating layer, a source, and a drain, the insulating layer being interposed between the channel and the gate electrode, wherein at least part of the organic semiconductor layer comprises the channel, and wherein the electrode comprises the gate electrode.

The organic material may comprise at least one macromolecule. The organic material may comprise at least one selected from the group consisting of substituted or unsubstituted polythiophene, substituted or unsubstituted polyparaphenylvinylene, substituted or unsubstituted polyparaphenylene, substituted or unsubstituted polyfluorene, substituted or unsubstituted polythiophenevinylene, substituted or unsubstituted polythiophene-heterocyclic aromatic group copolymer, F82T (Aldrich Inc.), and substituted or unsubstituted poly(3-hexylthiophene). In the method, forming the organic semiconductor layer may comprise using at least one selected from the group consisting of dipping, spin coating, spray coating, and Langmuir-Blodgett (LB) coating.

The method may further comprise annealing the organic semiconductor layer. The electric field may be applied while annealing the organic semiconductor layer. Annealing the organic semiconductor layer may be conducted at a temperature between about 100° C. and about 120° C. At least part of the organic material may be substantially molecularly ordered in at least a portion of the organic semiconductor layer. The organic material may be substantially molecularly ordered in a region of the organic semiconductor layer located up to about 50 Å from the surface. The electronic device may comprise a display device.

Another aspect of the invention provides an electronic device made by the method described above. The electronic device may comprise a display device. The electronic device may comprise a thin film transistor, the thin film transistor comprising a channel, a gate electrode, an insulating layer, a source, and a drain, the insulating layer being interposed between the channel and the gate electrode, and wherein at least part of the organic semiconductor layer comprises the channel.

Another aspect of the invention provides a TFT including: a gate electrode; source and drain electrodes insulated from the gate; a polymer organic semiconductor layer that is insulated from the gate electrode, is electrically connected to the source and drain electrodes, and includes a channel region that is molecularly ordered by applying a voltage to the gate electrode; and a gate insulating layer that insulates the gate electrode from the source and drain electrodes.

Yet another aspect of the invention provides a method of manufacturing a TFT, the method including: forming a gate insulating layer covering a gate electrode on an insulating substrate; forming source and drain electrodes in predetermined regions corresponding to ends of the gate electrode on the gate insulating layer; under the condition that an induced electric field is formed in a channel forming region of a polymer organic semiconductor layer by applying a voltage to the gate electrode, coating a polymer organic semiconductor on the source and drain electrodes and then annealing the coated polymer organic semiconductor, thus forming a polymer organic semiconductor layer including a molecularly ordered channel region.

Another aspect of the invention provides a flat panel display including the TFT described above at respective pixels of the flat panel display, wherein a pixel electrode is connected to a source electrode or drain electrode of the TFT.

### BRIEF DESCRIPTION OF THE DRAWINGS

The above and other features and advantages of the invention will become more apparent by the following description with reference to the attached drawings in which:

FIG. 1 is a cross-sectional view of a thin film transistor (TFT) according to an embodiment;

FIG. 2 is a cross-sectional view of a TFT according to one embodiment; and

FIG. 3 is a cross-sectional view of a flat panel display including a TFT according to another embodiment.

### DETAILED DESCRIPTION OF CERTAIN INVENTIVE EMBODIMENTS

A thin film transistor and a method of making the same according to embodiments of the invention will now be described in detail with reference to the accompanying drawings. In the drawings, like reference numerals indicate identical or functionally similar elements.

A thin film transistor (TFT) according to one embodiment includes an organic semiconductor layer made of a large molecular weight compound, a gate electrode, and a gate insulating layer interposed between the organic semiconductor layer and the gate electrode. When a positive (+) or negative (−) voltage is applied to the gate electrode, polarization occurs due to the alignment of molecular dipole moments in the gate insulating layer, thus inducing surface charges in a channel region of the polymer organic semiconductor layer. The induced surface charges allow the effective control of molecular ordering of the polymer organic semiconductor layer.

A degree of ordering of the polymer organic semiconductor layer can be controlled by changing the voltage applied to the gate electrode. In addition, the gate electrode can be used to selectively induce surface charges only in the active channel region of the polymer organic semiconductor layer so that the alignment effect of a crystalline growth mechanism can be activated.

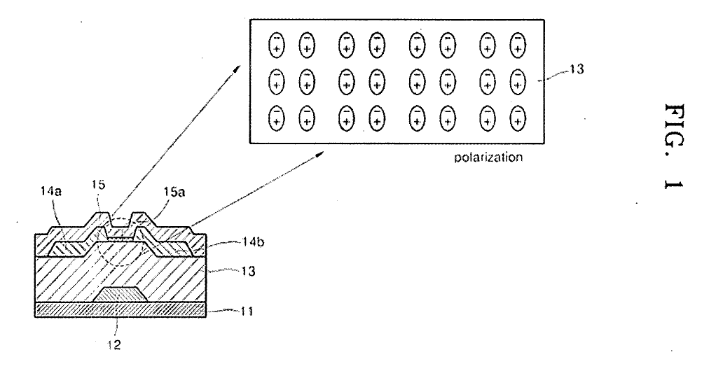

FIG. 1 illustrates how molecular dipole moments are aligned in the gate insulating layer, and thus induce surface charges in a channel region. In the illustrated TFT, surface charges are induced in the active channel region 15a of the organic semiconductor layer 15 made of macromolecules, and thus the polymer organic semiconductor can be molecularly ordered. The macromolecules of the organic semiconductor layer 15 include a polymeric compound, an oligomeric compound, or any other large molecular weight compounds that can form a layer using a method such as dipping, spin coating, or spray coating. For the sake of convenience, the organic semiconductor layer containing macromolecules are often referred to as a polymer organic semiconductor layer.

Referring to FIG. 1, when a negative (−) voltage is applied to the gate electrode 12, a molecular dipole moment is created in molecules of the gate insulating layer 13. Within the molecules, positive charges position toward the gate electrode 12 and negative charges position away from the gate electrode 12. As a result, negative surface charges are formed at the top surface of the insulating layer 13. During the formation or solidification of the organic semiconductor layer 15, the surface charges induce the macromolecules that form the semiconductor layer 15 to orient in a certain direction and align in response to the surface charge. For example, more positive portions of the macromolecules would orient toward the negative surface charges, and more negative portions of the macromolecules would orient away from the negative surface charges. This configuration provides a positive (+) charge region in the channel region 15a of the organic semiconductor layer 15 proximate to the surface of the gate insulating layer 13. The channel region 15a is suitable for carrier transportation. In FIG. 1, reference numerals 14a and 14b denote source and drain electrodes, respectively. Although not illustrated, a positive (+) voltage is applied to the gate electrode 12, a similar phenomenon occurs and accordingly the molecules forming the organic semiconductor layer 15 can be aligned.

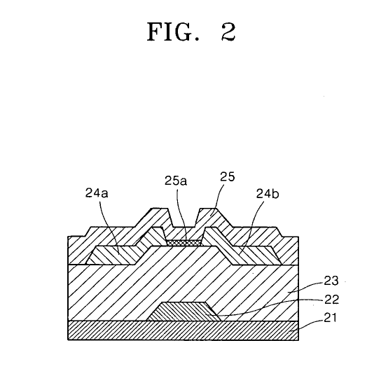

FIG. 2 illustrates a TFT according to one embodiment of the invention. The illustrated TFT includes a substrate 21, a gate electrode 22 overlying the substrate 21, a gate insulating layer 23 overlying the gate electrode 22, source and drain electrodes 24a and 24b overlying the gate insulating layer 23, and an organic semiconductor layer 25. A central portion of the layer 25 overlies the gate insulating layer 23, and is interposed between the source and drain electrodes 24a and 24b. In addition, portions of the organic semiconductor layer 25 overlie the source and drain electrodes 24a and 24b, as shown in FIG. 2. At least part of the central portion may constitute a channel region 25a. A skilled artisan will appreciate that various configurations of layer structures can be employed for a TFT.

The substrate 21 can be formed of any suitable substrate material. For example, the substrate 21 may be a glass substrate or a plastic substrate. In one embodiment, the plastic substrate is transparent and waterproof. In addition, the plastic substrate can have a flat surface, and can be easily processed.

The gate electrode 22 with a predetermined pattern is formed on the substrate 21. The gate electrode 22 may be formed of a metal or an alloy thereof. Examples of the metal includes, but are not limited to, Au, Ag, Cu, Ni, Pt, Pd, Al, Mo, an alloy of Al and Nd, and an alloy of Mo and W. In certain embodiments, the gate electrode 22 can be formed of a conductive polymer.

The gate insulating layer 23 is configured to cover and insulate the gate electrode 22. The gate insulating layer 23 may be formed of a material having a high dielectric constant that can be easily polarized. In one embodiment, the gate insulating layer 23 may be formed of silica, polymethylmethacrylate, Al₂O₃ (aluminum oxide), a mixture thereof, or a material having a dielectric constant between about 3.9 and about 10.

The source and drain electrodes 24a and 24b are formed on the gate insulating layer 23. The illustrated source and drain electrodes 24a and 24b overlap with parts of the gate electrode 22. In another embodiment, however, the source and drain electrodes 24a and 24b may have different configurations. The source and drain electrodes 24a and 24b may be formed of a noble metal having a work function of about 5.0 eV or higher in consideration of a material for an organic semiconductor layer. Examples of the noble metal having such a low work function include Au, Pd, Pt, Ni, Rh, Ru, Ir, Os, and alloys containing one or more of the foregoing.

As illustrated in FIG. 2, the polymer organic semiconductor layer 25 is deposited on the source and drain electrodes 24a and 24b and the gate insulating layer 23. The channel region 25a of the organic semiconductor layer 25 is interposed between the source and drain electrodes 24a and 24b. The organic semiconductor material in the channel region 25a is substantially molecularly ordered by applying a voltage to the gate electrode 22.

An organic semiconductor compound used to form the polymer organic semiconductor layer 25 may be either a p-type semiconductor or an n-type semiconductor compound. In one embodiment, the polymer organic semiconductor layer 25 may be formed of polythiophene or a derivative thereof, polyparaphenylvinylene or a derivative thereof, polyparaphenylene or a derivative thereof, polyfluorene or a derivative thereof, polythiophenevinylene or a derivative thereof, polythiophene-heterocyclic aromatic group copolymer or a derivative thereof, F82T (commercially available from Aldrich Inc.), poly(3-hexylthiophene) (P3HT, commercially available from Dow Chemical Inc.) or a derivative thereof. However, the material used to form the polymer organic semiconductor layer 25 is not limited thereto.

In one embodiment where the polymer organic semiconductor layer 25 is formed of a p-type polymer organic semiconductor, a negative (−) direct voltage is applied to the gate electrode 22 during formation or solidification of the organic semiconductor layer 25. The voltage applied to the gate electrode 22 may be in a range of about −100 V to about −50V. Then, molecular dipole moments are aligned in the gate insulating layer 23 with positive charges aligned toward the gate electrode 22 and negative charges aligned toward the organic semiconductor layer 25. Thus, negative surface charges are formed on the top surface of the insulating layer 23. During the formation or solidification of the organic semiconductor layer 25, the surface charges in turn induce the macromolecules to orient in a certain direction. For example, more positive portions of the macromolecules would orient toward the negative surface charges, and more negative portions of the macromolecules would orient away from the negative surface charges. This configuration provides a positive (+) charge region in the channel region 25a of the polymer organic semiconductor layer 25 proximate to the surface of the gate insulating layer 23.

In another embodiment where the polymer organic semiconductor layer 25 is formed of an n-type polymer organic semiconductor, a positive (+) direct voltage is applied to the gate electrode 22. The voltage applied to the gate electrode 22 may be in a range of about 50V to about 100 V. Then, molecular dipole moments are aligned in the gate insulating layer 23 with positive charges aligned toward the organic semiconductor layer 25 and negative charges aligned toward the gate electrode 22. This polarization within the insulating layer 23 forms positive surface charges on the top surface of the insulating layer 23. During the formation or solidification of the organic semiconductor layer 25, the positive surface charges induce certain orientation of the macromolecules. This configuration provides a negative (−) charge region in the channel region 25a of the polymer organic semiconductor layer 25 proximate to the surface of the gate insulating layer 23.

The thickness of the channel region 25a may be adjusted by changing the strength of the voltage applied to the gate electrode 23 during the formation and/or solidification by annealing the polymer organic semiconductor layer 25. In one embodiment, in the channel region 25a, a substantial portion of the macromolecules is molecularly ordered. For example, about 10, 20, 30, 40, 50, 60, 70, 80, or 90% of the macromolecules are oriented in a generally same direction, within proximity from the top surface of the insulating layer 23. The molecularly ordered region may reach up to about 10, 20, 30, 40, 50, 60, 70, 80, 90 or 100 Å from the top surface of the insulating layer 23. For example, the channel region 25a may be formed between about 0.1 Å and about 50 Å from the surface of the gate insulating layer 23.

The polymer organic semiconductor layer 25 having the molecularly ordered channel region 25a can be identified using an atomic force microscope (AFM) or through X ray diffraction analysis. The TFT has been described above with reference to FIG. 2. In other embodiments, the TFT may have various other layer configurations and structures.

A method of manufacturing a TFT according to an embodiment will now be described in detail with reference to FIG. 2. First, the gate electrode 22 is formed on the substrate 21, and the resulting structure is covered by the gate insulating layer 23. Then, the source and drain electrodes 24a and 24b are respectively formed on the gate insulating layer 23 at predetermined positions.

Next, a polymer organic semiconductor is coated or deposited on the source and drain electrodes 24a and 24b while an electric field is produced over the surface of the gate insulating layer 23 by applying a voltage to the gate electrode 22. The polymer organic semiconductor may be coated by dipping, spin coating, spray coating, or Langmuir-Blodgett (LB) coating. However, the coating method is not limited thereto.

Then, the resulting structure is subjected to an annealing step to cure the organic semiconductor layer 25. The annealing step is performed to crystallize the organic semiconductor compound. The annealing temperature may be in a range between about 100° C. and about 120° C.

In a TFT manufactured using the method according to the above embodiments, a polymer organic semiconductor layer including a channel region that is molecularly ordered by applying a voltage to the gate electrode can be more stable and have a higher carrier transporting capability than when other molecular ordering methods, for example, a molecular ordering method that uses an alignment layer, are used. In such a TFT, the active channel region of the polymer organic semiconductor layer is a charge transport medium having an increased packing density, and thus a greater current can flow between the source electrode and the drain electrode and the on/off ratio can be increased. The TFT is suitable for a large, reliable organic light emitting display, and for a large flexible display driving device.

Respective layers of the TFT can be formed using various methods, for example, depositing methods or coating methods selected according to a material used to form respective layers. The method of manufacturing a TFT described above may vary according to the structure of a TFT.

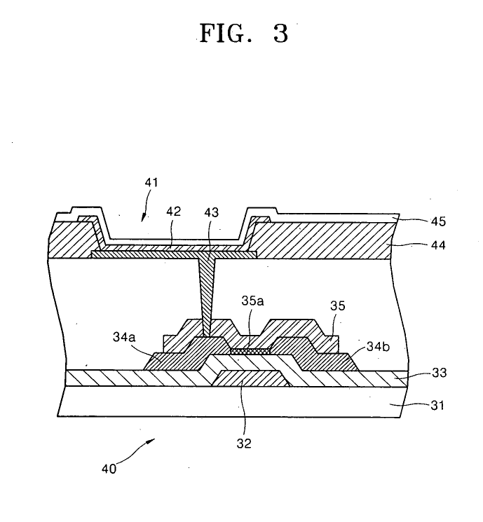

The TFT described above may be used in a flat panel display, such as a liquid crystal display (LCD) or an organic light emitting display. FIG. 3 is a cross-sectional view of an organic light emitting display including a TFT, which is an exemplary flat panel display according to an embodiment.

FIG. 3 illustrates a single sub-pixel of an organic light emitting display. Each sub-pixel includes an organic light emitting display device that emits light, and at least one TFT. The organic light emitting display can have various pixel patterns according to the color of light which the organic light emitting display device emits. For example, the organic light emitting display may include red, green, and blue pixels.

Referring to FIG. 3, a TFT includes a gate electrode 32 with a predetermined pattern formed on a substrate 31, and a gate insulating layer 33 covering the gate electrode 32. Source and drain electrodes 34a and 34b are formed on the gate insulating layer 33, and a polymer organic semiconductor layer 35 is formed on the source and drain electrodes 34a and 34b. A channel region 35a that is molecularly ordered by applying an electric field is formed between the source electrode 34a and the drain electrode 34b.

The TFT 40 is covered by a protecting layer and/or a planarization layer. The protecting layer and/or the planarization layer can be formed in a single layer structure or a multiple layer structure, and can be formed of an organic material, inorganic material, or organic/inorganic complex material.

An organic light emitting layer 42 of an organic light emitting display device 41 is formed on the protecting layer and/or the planarization layer in a trench defined by a pixel definition layer 44.

The organic light emitting display device 41 may emit red, green, or blue light according to the flow of current to display a predetermined image. The organic light emitting display device 41 includes a pixel electrode 43 connected to one of the source and drain electrodes 34a and 34b of the TFT 40, a facing electrode 45 covering the entire pixel, and an organic light emitting layer 42 that emits light. The organic light emitting layer 42 is interposed between the pixel electrode 43 and the facing electrode 45. However, the structure of the organic light emitting display is not limited thereto. In other embodiments, the organic light emitting display can have various other configurations and structures.

The organic light emitting layer 42 may be a low molecular weight organic layer or a high molecular weight organic layer. When the organic light emitting layer 42 is a low molecular weight organic layer, the organic light emitting layer 42 may include a hole injection layer (HIL), a hole transport layer (HTL), an emission layer (EML), an electron transport layer (ETL), an electron injection layer (EIL), and the like, and can have a single layer or multiple layer structure. The low molecular weight organic layer may be formed of copper phthalocyanine (CuPc), N,N′-Di(naphthalene-1-yl)-N,N′-diphenyl-benzidine (NPB), tris-8-hydroxyquinoline aluminum (Alq3), or the like. The low molecular weight organic layer can be formed by vacuum deposition.

When the organic light emitting layer 42 is a high molecular weight organic layer, the organic light emitting layer 42 may include a HTL and an EML. The HTL may be formed of PEDOT, and the EML may be formed of a polymer organic material such as a poly-phenylenevinylene (PPV)-based material or a polyfluorene-based material. These materials can be screen printed or inkjet printed to form the organic light emitting layer 42. The organic light emitting layer 42 is not limited to the above-described structures, and various embodiments can be used.

The pixel electrode 43 can act as an anode and the facing electrode 45 can act as a cathode. Alternatively, the pixel electrode 43 can act as a cathode and the facing electrode 42 can act as an anode.

For a liquid crystal display, a lower facing layer (not shown), as a lower substrate of the liquid crystal display, may cover the pixel electrode 43.

The TFTs according to the embodiments as described above can be used for pixels as illustrated in FIG. 3. Alternatively, the TFTs may be used in a driver circuit.

As described above, in a TFT according to the embodiments, an active channel region of a polymer organic semiconductor layer has a charge transport medium having an increased packing density so that a greater current can flow between the source electrode and the drain electrode and the on/off ratio can be increased. The TFT is suitable for a large, reliable organic light emitting display and for a large flexible display driving device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of making an electronic device comprising an organic semiconductor layer, the method comprising:
forming an organic semiconductor layer on a surface with an organic material; and
applying an electric field over the surface so as to align at least part of the organic material.

2. The method of claim 1, wherein the electric field is applied while depositing the organic material.

3. The method of claim 1, further comprising:
providing an electrode; and
providing an insulating layer over the electrode;
wherein the insulating layer provides the surface, on which the organic semiconductor layer is formed; and
wherein applying the electric field comprises applying a voltage to the electrode.

4. The method of claim 3, wherein the organic material comprises a p-type organic compound, and wherein the voltage is negative.

5. The method of claim 4, wherein the voltage ranges from about −100V to about −50V.

6. The method of claim 3, wherein the organic material comprises an n-type organic compound, and wherein the voltage is positive.

7. The method of claim 6, wherein the voltage ranges from about 50V to about 100V.

8. The method of claim 3, wherein the insulating layer comprises a material having a dielectric constant between about 3.9 and about 10.

9. The method of claim 3, wherein the electronic device comprises a thin film transistor, the thin film transistor comprising a channel, a gate electrode, an insulating layer, a source, and a drain, the insulating layer being interposed between the channel and the gate electrode, wherein at least part of the organic semiconductor layer comprises the channel, and wherein the electrode comprises the gate electrode.

10. The method of claim 1, wherein the organic material comprises at least one macromolecule.

11. The method of claim 10, wherein the organic material comprises at least one selected from the group consisting of substituted or unsubstituted polythiophene, substituted or unsubstituted polyparaphenylvinylene, substituted or unsubstituted polyparaphenylene, substituted or unsubstituted polyfluorene, substituted or unsubstituted polythiophenevinylene, substituted or unsubstituted polythiophene-heterocyclic aromatic group copolymer, F82T (Aldrich Inc.), and substituted or unsubstituted poly(3-hexylthiophene).

12. The method of claim 1, wherein forming the organic semiconductor layer comprises using at least one selected from the group consisting of dipping, spin coating, spray coating, and Langmuir-Blodgett (LB) coating.

13. The method of claim 1, further comprising annealing the organic semiconductor layer.

14. The method of claim 13, wherein the electric field is applied while annealing the organic semiconductor layer.

15. The method of claim 13, wherein annealing the organic semiconductor layer is conducted at a temperature between about 100° C. and about 120° C.

16. The method of claim 1, wherein the electronic device comprises a display device.

17. An electronic device made by the method of claim 1.

18. The device of claim 17, wherein the electronic device comprises a display device.

19. The device of claim 17, wherein the electronic device comprises a thin film transistor, the thin film transistor comprising a channel, a gate electrode, an insulating layer, a source, and a drain, the insulating layer being interposed between the channel and the gate electrode, and wherein at least part of the organic semiconductor layer comprises the channel.

20. The method of claim 17, wherein at least part of the organic material is substantially molecularly ordered in at least a portion of the organic semiconductor layer.

21. The method of claim 17, wherein the organic material is substantially molecularly ordered in a region of the organic semiconductor layer located up to about 50 Å from the surface.
